(19) United States
(12) Patent Application Publication
(10) Pub. No.: US 2015/0276820 A1
(43) Pub. Date: Oct. 1, 2015

(54) METHOD AND SYSTEM FOR MONITORING, METERING, AND REGULATING POWER CONSUMPTION

(71) Applicant: International Business Machines Corporation, Armonk, NY (US)

(72) Inventors: Robert K. Floyd, III, Clermont, FL (US); Mahesh Viswanathan, Yorktown Heights, NY (US)

(73) Assignee: International Business Machines Corporation, Armonk, NY (US)

(21) Appl. No.: 14/231,886

(22) Filed: Apr. 1, 2014

(51) Int. Cl. G01R 19/00

(52) U.S. Cl. CPC G01R 19/00

(57) ABSTRACT

A method and a system for monitoring power consumption are provided. The system comprises a breaker including a server for dynamically distributing network configuration parameters and an active RFID device, and further comprises a device including a client for dynamically distributing network configuration parameters and a passive RFID device, wherein the device is a switch or a receptacle. In the method and the system, the device is registered by the breaker by passing information of the passive RFID device to the active RFID device; the breaker and the devices are connected through Ethernet over a power line. The server is configured to provide a service to the client.

### TECHNICAL FIELD OF THE INVENTION

The present invention relates generally to power management, and more particularly to monitoring, metering, and regulating power consumption.

### BACKGROUND

Most outlets and power sinks are completely passive (i.e., only providing power) and do not provide any information about the how much is being consumed via the outlets or the power sinks. Some intelligent power outlets allow for a measurement and a user interface. Passive receptacles often connect to a central power meter and therefore aggregate power consumption in a room, home, or building can be measured.

Total residential and commercial electricity use in the US amounts to 66% of the total produced power. Usually, metering is done at an aggregate level. Each room, home, or building is as one power meter; therefore, there is little breakdown information available. For example, information about how much power consumption of an individual appliance and about what is a fraction of power consumption over total power consumption in a room, home, or building is unknown. In an example of a data center where many servers consume a power strip, only information at an aggregate level is known. Knowing how much is consumed by an individual unit (for example, an individual appliance in a home or an individual server in a data center) is often the first step in trying to reduce power consumption or making business decisions.

### SUMMARY

In one aspect, a method for monitoring power consumption is provided. The method comprises providing a breaker that comprises a server for dynamically distributing network configuration parameters and an active RFID (Radio Frequency Identification) device. The method further comprises providing a device that comprises a client for dynamically distributing network configuration parameters and a passive RFID device, wherein the device is one of a receptacle and a switch. The method further comprises bringing the breaker and the device in proximity to each other such that the active RFID device reads information from the passive RFID device and the breaker registers the device. The method further comprises connecting the breaker and the device through Ethernet over a power line. The method further comprises configuring the server to provide a service to the client.

In another aspect, a system for monitoring power consumption is provided. The system comprises a breaker and a device, wherein the device is one of a receptacle and a switch. The breaker comprises a server for dynamically distributing network configuration parameters and an active RFID (Radio Frequency Identification) device. The device comprises a client for dynamically distributing network configuration parameters and a passive RFID device. In the system, the device is registered by the breaker by passing information of the passive RFID device to the active RFID device. In the system, the breaker and the device are connected through Ethernet over a power line. In the system, the server is configured to provide a service to the client.

### BRIEF DESCRIPTION OF THE SEVERAL VIEWS OF THE DRAWINGS

FIG. 1(A) is a diagram illustrating a system of a smart breaker, a switch, and a receptacle connected through Ethernet over a power line, in accordance with one embodiment of the present invention.

FIG. 1(B) is a diagram illustrating components of a smart breaker in a system shown in FIG. 1(A), in accordance with one embodiment of the present invention.

FIG. 1(C) is a diagram illustrating components of a switch or a receptacle shown in a system in FIG. 1(A), in accordance with one embodiment of the present invention.

FIG. 2 is a flowchart illustrating steps for connecting a smart breaker and a device (a switch or a receptacle) through Ethernet over a power line, in accordance with one embodiment of the present invention.

FIG. 3 is a flowchart illustrating steps for a DHCP service provided by a smart breaker to a device (a switch or a receptacle) through Ethernet over a power line, in accordance with one embodiment of the present invention.

FIG. 4 is a flowchart illustrating steps, implemented by computer programs on a smart breaker and programs on a device (a switch or a receptacle), for monitoring and metering power consumption, in accordance with one embodiment of the present invention.

FIG. 5 is a flowchart illustrating steps for regulating power consumption by using a smart breaker connected to a device (a switch or a receptacle) through Ethernet over a power line, in accordance with one embodiment of the present invention.

### DETAILED DESCRIPTION

Embodiments of the present invention disclose a method for monitoring and reporting on power usage with an inexpensive approach: using RFID and DHCP technologies and using no moving parts. This allows each receptacle or switch to report on power consumption at small time increments and a collection point attached to a URL for viewing, gathering, and reporting data. Embodiments of the present invention provide a system for monitoring, metering, and reporting power usage of devices connected to power sources. The system allows users to monitor the consumption of power per appliance attached to a switch or power receptacle, and allows for predictive decision-making on operate-as-is vs. buying new.

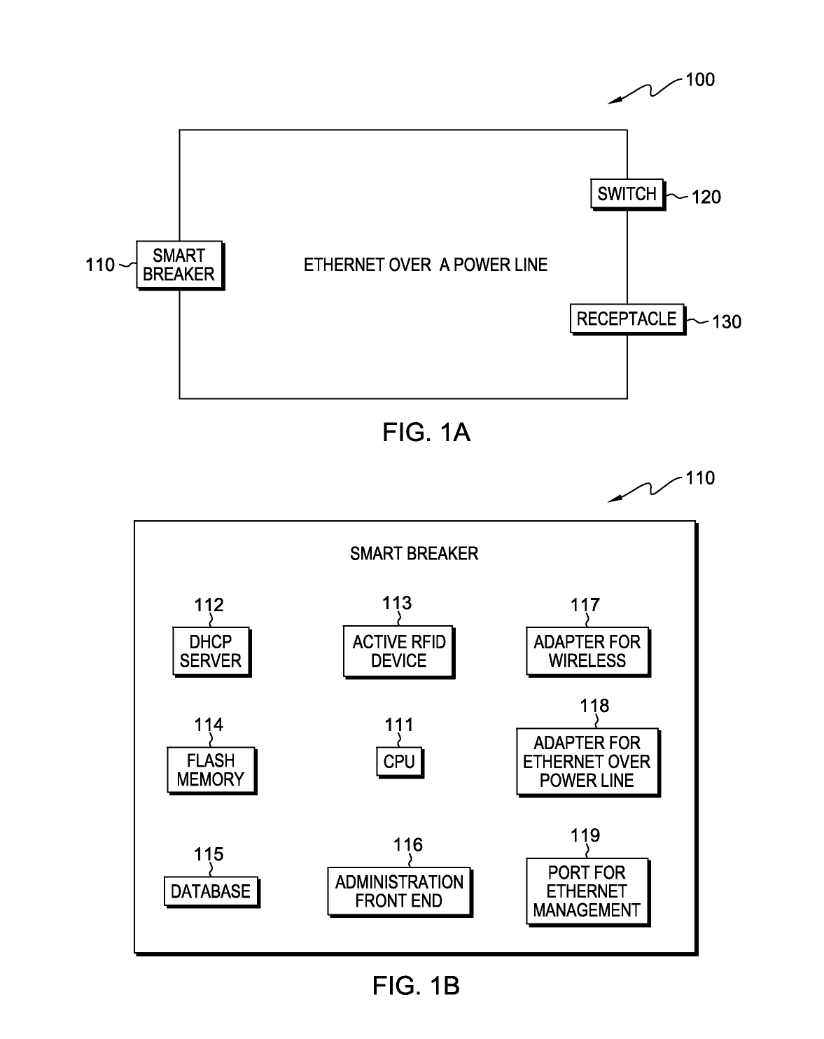

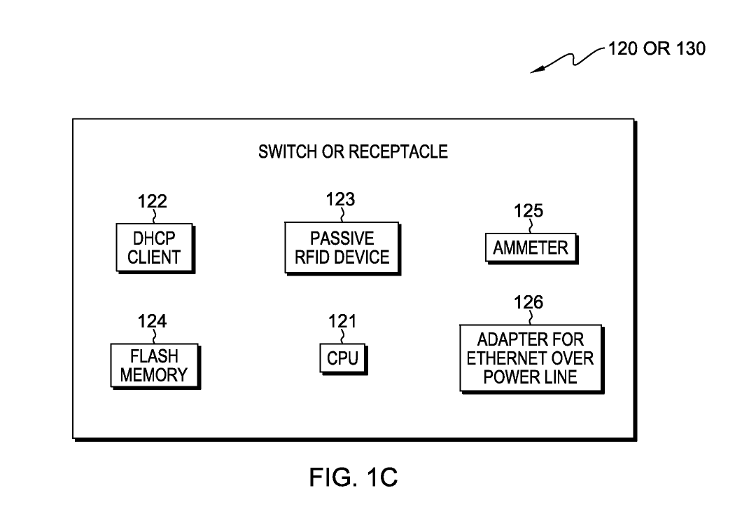

FIG. 1(A) is a diagram illustrating system 100 of smart breaker 110, switch 120, and receptacle 130 connected through Ethernet over a power line, in accordance with one embodiment of the present invention. In system 100, smart breaker 110, switch 120, and receptacle 130, which have Ethernet ports and power line adapters, establish an Ethernet connection using the existing electrical wiring. Smart breaker 110 is like a regular breaker in an electric circuit; however, unlike a regular breaker, the smart breaker comprises a DHCP (Dynamic Host Configuration Protocol) server and an active RFID (Radio Frequency Identification) device. The DHCP is a standardized networking protocol used on networks for dynamically distributing network configuration parameters, such as IP addresses for interfaces and services. Switch 120 or receptacle 130 is like a regular switch or receptacle in an electric circuit; however, unlike a regular switch or receptacle, switch 120 or receptacle 130 comprises a DHCP client and a passive RFID device. Smart breaker 110 communicates with switch 120 and receptacle 130 through Ethernet over a power line.

FIG. 1(B) is a diagram illustrating components of smart breaker 110 in system 100 shown in FIG. 1(A), in accordance with one embodiment of the present invention. Smart breaker 110 comprises DHCP server 112. DHCP server 112 creates a domain of DHCP clients on registered devices (switches or receptacles) in a network which is Ethernet over a power line; thus, smart breaker 110 can monitor and meter power consumption of the registered devices (e.g., switches or receptacles), and can receive, from the registered devices, reports of power consumption. Smart breaker 110 further comprises active RFID (Radio Frequency Identification) device 113, which mates with passive RFID devices on the respective devices (e.g., switches or receptacles), registers the respective devices, and records, on database 115, a unique ID of the registered devices. Smart breaker 110 has CPU (Central Processing Unit) 111 which performs basic arithmetical, logical, and input/output operations of smart breaker 110. Smart breaker 110 also has small flash memory 114. Smart breaker 110 further comprises adapter 118 for Ethernet over a power line; the adapter is used to connect smart breaker 110 to Ethernet over a power line. Smart breaker 110 may further comprise adapter 117 for wireless; the adapter is used for wireless connection.

Referring to FIG. 1(B), smart breaker 110 further comprises port 119 for Ethernet management and administration front end 116, which allow a user to administrate the smart breaker's capacities and manage the registered devices through Ethernet over a power line. The administration or management is carried out through a URL (Uniform Resource Locator) which has a unique IP address for smart breaker 110, a user ID, and/or a password. The user may log onto smart breaker 110 to set a hostname, set an IP address and subset, set a DHCP range, and set up NTP (Network Time Protocol) service of system 100. The user may log onto smart breaker 110 to name the registered devices (e.g., switches and receptacles). The user may log onto smart breaker 110 to regulate power consumption by setting on/off schedules of the registered devices which are connected through Ethernet over a power line.

FIG. 1(C) is a diagram illustrating components of switch 120 or receptacle 130 shown in a system in FIG. 1(A), in accordance with one embodiment of the present invention. Switch 120 or receptacle 130 is an example of the registered devices which are connected to smart breaker 110 through Ethernet over a power line. Switch 120 or receptacle 130 comprises DHCP (Dynamic Host Configuration Protocol) client 122. DHCP client 122 requests DHCP server 112 for a DHCP service (such as assigning an IP address of switch 120 or receptacle 130). After DHCP server 112 processes the request, DHCP client 122 receives the IP address, options for a log destination and NTP (Network Time Protocol), and a schedule for reporting data of power consumption. Switch 120 or receptacle 130 further comprises passive RFID device 123; the passive RFID device mates with active RFID device 113 and has the switch or receptacle registered by smart breaker 110. Switch 120 or receptacle 130 further comprises CPU (Central Processing Unit) 121 which performs basic arithmetical, logical, and input/output operations of switch 120 or receptacle 130. Switch 120 or receptacle 130 also has flash memory 124. Switch 120 or receptacle 130 further comprises adapter 126 for Ethernet over a power line; the adapter is used to connect the switch or the receptacle to Ethernet over a power line. Switch 120 or receptacle 130 further comprises ammeter 125 for measuring electric current. In the embodiment, switch 120 or receptacle 130 has no local storage; the switch or the receptacle sends data of measuring electric current to smart breaker 110.

Since the power flow is continuous with the nearest air-gap being the power company's transformer, a secure way of segregating households or units divided by breakers is needed. System 100 secures this separation in two ways: (1) Code of DHCP server 112 and DHCP client 122 is implemented in silicon. (2) Unpaired or unregistered devices (switches or receptacles) are left unmonitored and will not be paired or registered with any DHCP server.

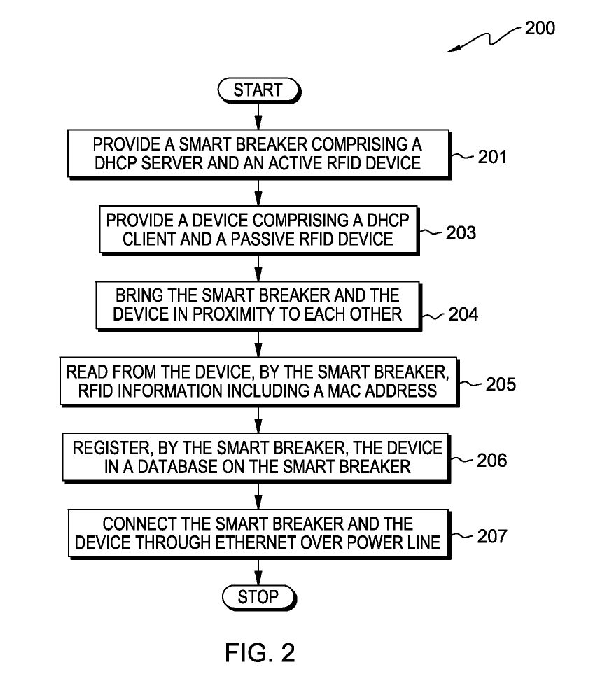

FIG. 2 is flowchart 200 illustrating steps for connecting a smart breaker (such as smart breaker 110 shown in FIG. 1(A)) and a device (such as switch 120 or receptacle 130 shown in FIG. 1(A)) through Ethernet over a power line, in accordance with one embodiment of the present invention. At step 201, a user provides a smart breaker that comprises a DHCP server (such as DHCP server 112 shown in FIG. 1(B)) and an active RFID device (such as active RFID device 113 shown in FIG. 1(B)). At step 203, the user provides a device that comprises a DHCP client (such as DHCP client 122 shown in FIG. 1(C)) and a passive RFID device (such as passive RFID device 123 shown in FIG. 1(C)). At step 204, the user brings the smart breaker and the device in proximity to each other.

Referring to FIG. 2, at step 205, the smart breaker reads RFID information of the device. The RFID information includes an MAC (Media Access Control) address. The RFID information of the device is read when the smart breaker and the device are brought in proximity to each other. At step 206, the smart breaker registers the device in a database (such as database 115 shown in FIG. 1(B)) on the smart breaker. Through these steps, the smart breaker and the device are paired. The smart breaker stores the RFID information of the device in the database. Then, at step 207, the user connects the smart breaker and the device though Ethernet over a power line. The device, as well as the smart breaker, is installed in an electric circuit. For example, smart breaker 110, switch 120, and receptacle 130 are connected through Ethernet over a power line, as shown as in FIG. 1(A). The smart breaker and the device can communicate through Ethernet over a power line.

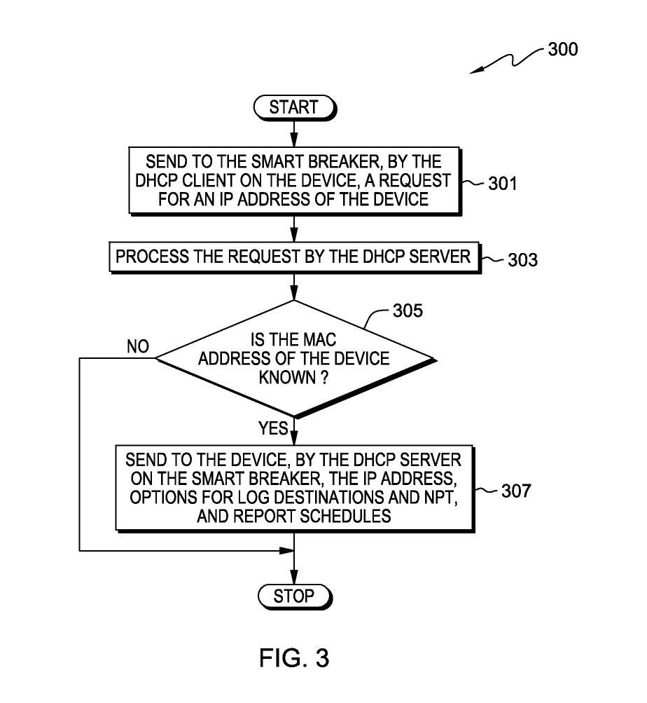

FIG. 3 is flowchart 300 illustrating steps for DHCP service provided by a smart breaker (such as smart breaker 110 shown in FIG. 1(A)) to a device (such as switch 120 or receptacle 130 shown in FIG. 1(A)) through Ethernet over a power line, in accordance with one embodiment of the present invention. When a load (for example an appliance) is connected to a receptacle or a switch is thrown on, a DHCP client (such as DHCP client 122 shown in FIG. 1(C)) on the device, at step 301, sends to the smart breaker a request for an IP address of the device. At step 303, a DHCP server (such as DHCP server 112 shown in FIG. 1(B)) processes the request. At decision block 305, the DHCP server determines whether an MAC address of the device is known. If the device and the smart break have been paired in the steps shown in FIG. 2, the MAC address has been stored in a database on the smart breaker and it has been known to the smart breaker. In response to determining that the MAC address of the device is known (YES branch of decision block 305), the DHCP server at step 307 sends to the DHCP client the IP address, options for log destinations and NTP (Network Time Protocol), and report schedules. Since the pairing process in the steps shown in FIG. 2 has already established the validity of the device as part of the domain, the DHCP server now assigns an IP address to the DHCP client which makes the request. Log destinations and NTP can be customizable on the DHCP server so that the DHCP server can run those services and have the client get time and send logs to the breaker. Alternatively, the DHCP server can instruct the DHCP client to get time and send logs somewhere else, such as a dedicated syslog or a NTP server running elsewhere on the LAN. The DHCP server stores the IP address of the device in the memory (such as flash memory 114 shown in FIG. 1(B)) of the device.

In response to determining that the MAC address of the device is unknown (NO branch of decision block 305), the DHCP server does not respond to the request of the DHCP client. For example, if the device and the smart breaker are not paired through the pairing process in the steps shown in FIG. 2, the request made by the DHCP client is not responded to by the DHCP server; therefore, the device will remain unmonitored.

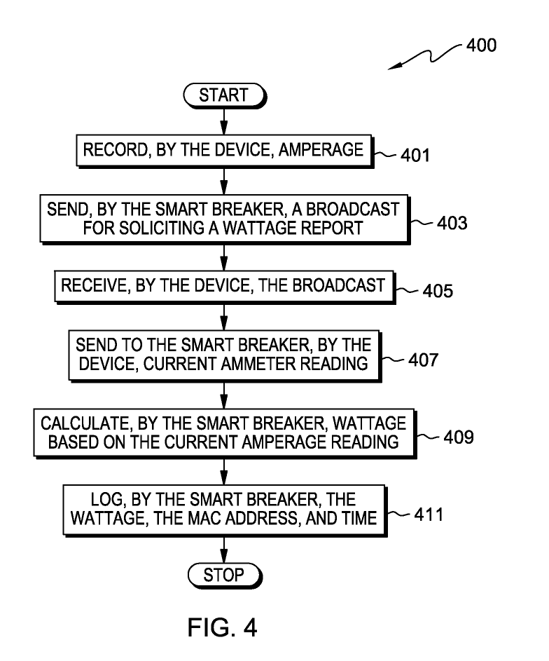

FIG. 4 is flowchart 400 illustrating steps, implemented by computer programs on a smart breaker (such as smart breaker 110 shown in FIG. 1(A)) and computer programs on a device (such as switch 120 or receptacle 130 shown in FIG. 1(A)), for monitoring and metering power consumption, in accordance with one embodiment of the present invention. The smart breaker and the device are paired through steps shown in FIG. 2, and the DHCP service is provided through steps shown in FIG. 3; therefore, the device is capable of monitoring power usage and passing that information to the smart breaker through Ethernet over a power line. This allows for monitoring and metering power usage at the device (either a receptacle or a switch).

Referring to FIG. 4, at step 401, the device (such as switch 120 or receptacle 130) records amperage. For example, recording amperage is carried out by ammeter 125 (shown in FIG. 1(C)) on switch 120 or receptacle 130. At step 403, the smart breaker (such as smart breaker 110) sends a broadcast for soliciting a wattage report. The smart breaker periodically sends the broadcast to all registered devices. At step 405, the device receives the broadcast. At step 407, the device sends to the smart breaker current ammeter reading. At step 409, the smart breaker calculates wattage based on the current ammeter reading. At step 411, the smart breaker logs the wattage, the MAC address of the device, and time. In this way, all registered devices connected to the smart breaker through Ethernet over a power line can be metered and monitored. The user can log onto the smart breaker to check wattage of the all registered devices.

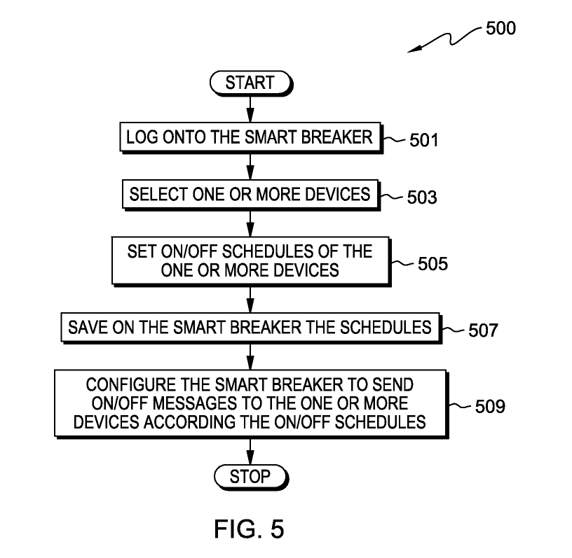

FIG. 5 is flowchart 500 illustrating steps for regulating power consumption by using a smart breaker (such as smart breaker 110 shown in FIG. 1(A)) connected to a device (such as switch 120 or receptacle 130 shown in FIG. 1(A)) through Ethernet over a power line, in accordance with one embodiment of the present invention.

Referring to FIG. 5, at step 501, a user logs onto the smart breaker. The user can log onto the smart breaker through a URL (Uniform Resource Locator) which has a unique IP address for the smart breaker, a user ID, and/or a password. For example, the user accesses the smart breaker through port 119 for Ethernet management and administration front end 116 of smart breaker 110 (shown in FIG. 1(B)). At step 503, the user selects one or more devices from the registered devices. The one or more devices are targets for the user to regulate power consumption. At step 505, the user sets on/off schedules of the one or more devices. At step 507, the user saves the schedules on the smart breaker. At step 509, the user configures the smart breaker to send on/off messages to the one or more devices, according to the on/off schedules. Thus, the smart breaker regulates power consumption of the one or more devices (switches or receptacles) through Ethernet over a power line.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network (LAN), a wide area network (WAN), and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture, including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A method for monitoring power consumption, the method comprising:
providing a breaker that comprises a server for dynamically distributing network configuration parameters and an active RFID (Radio Frequency Identification) device;
providing a device that comprises a client for dynamically distributing network configuration parameters and a passive RFID device, wherein the device is one of a receptacle and a switch;
bringing the breaker and the device in proximity to each other, such that the active RFID device reads information from the passive RFID device and the breaker registers the device;
connecting the breaker and the device through Ethernet over a power line; and
configuring the server to provide a service to the client.

2. The method of claim 1, further comprising:
configuring an ammeter on the device to record amperage;
configuring the breaker to calculate wattage based on the amperage;
configuring the breaker to log the wattage; and
retrieving a record of the wattage by accessing the breaker through an IP address of the breaker.

3. The method of claim 1, further comprising:
logging onto the breaker;
setting an on/off schedule of the device; and
configuring the breaker to send to the device on/off messages according to the on/off schedule.

4. The method of claim 1, further comprising:
receiving, by the server on the breaker, from the client on the device a request for an IP address of the device;
determining, by the server, whether the device is registered; and
assigning the IP address of the device, in response to determining that the device is registered.

5. The method of claim 1, further comprising:
sending, by the client on the device, to the server on the breaker a request for an IP address of the device; and
receiving, by the client, from the server the IP address of the device.

6. The method of claim 1, further comprising:
reading, by the ammeter on the device, amperage;
sending, by the breaker, a broadcast for soliciting a wattage report;
receiving, by the device, the broadcast;
sending, by the device, ammeter reading to the breaker;
calculating, by the breaker, wattage based on the ammeter reading; and
logging, by the breaker, the wattage, a MAC (Media Access Control) address of the device, and time of reading the amperage.

7. The method of claim 1, wherein the information from the passive RFID device includes a MAC address of the device.

8. The method of claim 1, wherein the breaker comprises an administration front end for a user to access the breaker and to manage the Ethernet over the power line.

9. The method of claim 1, wherein the breaker comprises a port for Ethernet management.

10. The method of claim 1, wherein each of the breaker and the device comprises an adapter for the Ethernet over the power line.

11. A system for monitoring power consumption, the system comprising:
a breaker that comprises a server for dynamically distributing network configuration parameters and an active RFID (Radio Frequency Identification) device;
a device that comprises a client for dynamically distributing network configuration parameters and a passive RFID device, wherein the device is one of a receptacle and a switch;
the device registered by the breaker by passing information of the passive RFID device to the active RFID device;
the breaker and the device being connected through Ethernet over a power line; and
the server being configured to provide a service to the client.

12. The system of claim 11, further comprising:
an ammeter on the device, the ammeter reading amperage;
wherein the breaker is capable of calculating wattage based on the amperage;
wherein the breaker is capable of logging the wattage; and
wherein the breaker is accessible for a user to retrieve a record of the wattage through an IP address of the breaker.

13. The system of claim 11, wherein the breaker is configured so as to send to the device on/off messages according to an on/off schedule of the device, the on/off schedule of the device is set by the user.

14. The system of claim 11, wherein the server on the breaker receives from the client on the device a request for an IP address of the device, determines whether the device is registered, and assigns, in response to determining that the device is registered, the IP address of the device.

15. The system of claim 11, wherein the client on the device sends to the server on the breaker a request for an IP address of the device, and receives from the server the IP address of the device.

16. The system of claim 11, wherein metering power consumption comprises:
reading, by the ammeter on the device, amperage;
sending, by the breaker, a broadcast for soliciting a wattage report;
receiving, by the device, the broadcast;
sending, by the device, ammeter reading to the breaker;
calculating, by the breaker, wattage based on the ammeter reading; and
logging, by the breaker, the wattage, a MAC (Media Access Control) address of the device, and time of reading the amperage.

17. The system of claim 11, wherein the information from the passive RFID device includes a MAC address of the device.

18. The system of claim 11, wherein the breaker comprises an administration front end for the user to access the breaker and to manage the Ethernet over the power line.

19. The system of claim 11, wherein the breaker comprises a port for Ethernet management.

20. The system of claim 11, wherein each of the breaker and the device comprises an adapter for the Ethernet over the power line.
